(19) United States
(12) Patent Application Publication
(10) Pub. No.: US 2018/0261632 A1
(43) Pub. Date: Sep. 13, 2018

(54) PRODUCTION METHOD OF ARRAY SUBSTRATE AND ARRAY SUBSTRATE

(71) Applicant: BOE Teachnology Group Co., Ltd., Beijing (CN)

(72) Inventor: Seungjin Choi, Beijing (CN)

(21) Appl. No.: 15/787,901

(22) Filed: Oct. 19, 2017

(30) Foreign Application Priority Data
Mar. 10, 2017 (CN) 201710144492.5

(51) Int. Cl. H01L 27/12; H01L 29/786; H01L 29/66

(52) U.S. Cl. CPC H01L 27/1262; H01L 29/78675; H01L 27/1251; H01L 29/7869; H01L 27/1237; H01L 29/66757; H01L 29/66969; H01L 27/1225

(57) ABSTRACT

This disclosure provides a production method of an array substrate and an array substrate. The production method of this array substrate comprises: forming a polycrystalline silicon layer on a base, wherein the base comprises a first active area, a second active area, and a non-active area; forming an oxide semiconductor layer on the polycrystalline silicon layer; and forming a first active layer on the first active area and forming a second active layer on the second active area by using a single patterning process, wherein the first active layer is composed of the polycrystalline silicon layer, and the second active layer is composed of the oxide semiconductor layer and the polycrystalline silicon layer.

### CROSS-REFERENCE TO RELATED APPLICATION

This invention claims the priority of Chinese Patent Application No. 201710144492.5 filed on Mar. 10, 2017, the entire contents of which are incorporated herein by reference.

### TECHNICAL FIELD

This disclosure relates to the field of display, in particular, to a production method of an array substrate and an array substrate.

### BACKGROUND ART

In the production of a thin film transistor (TFT) array substrate of a display panel, a low temperature polycrystalline oxide (LTPO) process is a novel technique which produces a TFT array substrate by concurrently using a low temperature polycrystalline silicon (LTPS) process and an oxide process.

### SUMMARY OF THE INVENTION

An embodiment of this invention provides a production method of an array substrate, comprising the steps of: forming a polycrystalline silicon layer on a base, wherein the base comprises a first active area, a second active area, and a non-active area; forming an oxide semiconductor layer on the polycrystalline silicon layer; and forming a first active layer on the first active area and forming a second active layer on the second active area by using a single patterning process, wherein the first active layer is composed of the polycrystalline silicon layer, and the second active layer is composed of the oxide semiconductor layer and the polycrystalline silicon layer.

In one embodiment, the patterning process comprises the steps of: Step one: forming a first protective layer at the first active area and forming a second protective layer at the second active area by using a single mask, wherein the thickness of the first protective layer is less than that of the second protective layer; Step two: removing the oxide semiconductor layer and the polycrystalline silicon layer at the non-active area by etching; Step three: removing the whole of the first protective layer and a part of the second protective layer to expose the oxide semiconductor layer below the first protective layer; Step four: removing the exposed oxide semiconductor layer by etching to form the first active layer composed of the polycrystalline silicon layer; and Step five: removing the remainder of the second protective layer to form the second active layer composed of the oxide semiconductor layer and the polycrystalline silicon layer.

In one embodiment, it further comprises: a step of forming a passivation layer on the oxide semiconductor layer before performing the patterning process, wherein the patterning process comprises: Step one: forming a first protective layer at the first active area and forming a second protective layer at the second active area by using a single mask, wherein the thickness of the first protective layer is less than that of the second protective layer; Step two: removing the passivation layer, the oxide semiconductor layer, and the polycrystalline silicon layer at the non-active area by etching; Step three: removing the whole of the first protective layer and a part of the second protective layer to expose the passivation layer below the first protective layer; Step four: removing the exposed passivation layer and the oxide semiconductor layer therebelow by etching to form the first active layer composed of the polycrystalline silicon layer; and Step five: removing the remainder of the second protective layer to form the second active layer composed of the oxide semiconductor layer and the polycrystalline silicon layer, and remaining the passivation layer on the second active layer.

In one embodiment, the etching in the Step two and the Step four is dry etching.

In one embodiment without a passivation layer, in the Step two, the oxide semiconductor layer and the polycrystalline silicon layer at the non-active area are sequentially removed in an order of wet etching and dry etching, and in the Step four, the exposed oxide semiconductor layer is removed by wet etching.

In one embodiment with a passivation layer, in the Step two, the passivation layer, the oxide semiconductor layer, and the polycrystalline silicon layer at the non-active area are sequentially removed in an order of dry etching, wet etching, and dry etching.

In one embodiment with a passivation layer, in the Step four, the exposed passivation layer and the oxide semiconductor layer therebelow are sequentially removed in an order of wet etching and dry etching.

In one embodiment, the material of the oxide semiconductor layer comprises at least one of indium gallium zinc oxide, indium gallium oxide, indium tin zinc oxide, and aluminum zinc oxide.

In one embodiment with a passivation layer, it further comprises the steps of: forming a gate insulating layer; forming a first gate electrode in the first active area and a second gate electrode in the second active area; forming an interlayer insulating layer; and forming a first source electrode and a first drain electrode in the first active area, and a second source electrode and a second drain electrode in the second active area, wherein the first source electrode and the first drain electrode are each connected to the first active layer through a via hole which penetrates the interlayer insulating layer and the gate insulating layer, and the second source electrode and the second drain electrode are each connected to the second active layer through a via hole which penetrates the interlayer insulating layer, the gate insulating layer, and the passivation layer.

An embodiment of this invention further provides an array substrate, comprising: a base, a gate electrode insulating layer, at least one gate electrode, at least one source electrode, and at least one drain electrode, wherein the base has a first active area and a second active area, a first active layer is provided on the first active area and the first active layer is composed of a polycrystalline silicon layer, a second active layer is provided on the second active area and the second active layer is composed of a polycrystalline silicon layer and an oxide semiconductor layer formed on the polycrystalline silicon layer, and the polycrystalline silicon layer in the first active layer and the polycrystalline silicon layer in the second active layer are formed from the same polycrystalline silicon layer.

In one embodiment, a passivation layer is further provided above the second active layer.

In one embodiment, the material of the oxide semiconductor layer comprises at least one of indium gallium zinc oxide, indium gallium oxide, indium tin zinc oxide, and aluminum zinc oxide.

In one embodiment with a passivation layer, the array substrate further comprises an interlayer insulating layer, the at least one gate electrode comprises a first gate electrode and a second gate electrode, the at least one source electrode comprises a first source electrode and a second source electrode, the at least one drain electrode comprises a first drain electrode and a second drain electrode, the gate insulating layer is provided above the first active layer and the passivation layer, the first gate electrode and the second gate electrode are provided above the gate insulating layer, the interlayer insulating layer is provided above the first gate electrode and the second gate electrode, the first source electrode, the first drain electrode, the second source electrode, and the second drain electrode are formed above the interlayer insulating layer, wherein the first source electrode and the first drain electrode are each connected to the first active layer through a via hole which penetrates the interlayer insulating layer and the gate insulating layer, and the second source electrode and the second drain electrode are each connected to the second active layer through a via hole which penetrates the interlayer insulating layer, the gate insulating layer, and the passivation layer.

### DESCRIPTION OF DRAWINGS

In order to illustrate the technical solutions in embodiments of this invention more clearly, accompanying drawings of embodiments will be simply illustrated below. It is apparent that the accompanying drawings described below are merely some embodiments related to this invention but not limitations of this invention.

FIG. 1 is a structural schematic diagram of an LTPO TFT array substrate in the prior art.

FIG. 2 is a structural schematic diagram of an LTPO TFT array substrate provided by an embodiment of this invention.

FIGS. 3-10 are procedure graphs showing the production procedures of the active layer of the TFT array substrate in FIG. 2 according to an embodiment of this invention.

FIG. 11 is a flow chart showing the production procedures of the active layer of the TFT array substrate in FIG. 2 according to an embodiment of this invention.

FIG. 12 is a flow chart showing specific contents of step S205 in FIG. 11 according to an embodiment of this invention.

### DESCRIPTION OF EMBODIMENTS

This disclosure may provide a production method of an array substrate, which can simplify the procedures and improve the production, as well as an array substrate.

In this disclosure, since an active layer of an LTPS TFT and an active layer of an oxide TFT can be concurrently formed by a single patterning process, the procedures can be simplified and the production can be improved. Furthermore, since the active layer of the oxide TFT array substrate comprises an oxide semiconductor layer and a polycrystalline silicon layer therebelow, it is advantageous to block ultraviolet by forming the polycrystalline silicon layer below the oxide semiconductor layer for the oxide semiconductor layer which is highly sensitive to ultraviolet.

In order to enable objects, technical solutions, and advantages of embodiments of this invention to be clearer, technical solutions of embodiments of this invention will be described clearly and fully below in conjunction with accompanying drawings of embodiments of this invention. Obviously, the embodiments described are a part of the embodiments of this invention, rather than all embodiments. Based on the embodiments described of this invention, all other embodiments obtained by those of ordinary skill in the art without performing inventive work belong to the scope protected by this invention.

Unless defined otherwise, technical terms or scientific terms used in this disclosure should have general meanings as understood by those of ordinary skill in the art to which this invention belongs. The word, such as “first”, “second”, or the like, used in this disclosure does not represent any order, number, or importance, but is used to distinguish different structural parts. The word, such as “include”, “comprise”, “have”, or the like, used in this disclosure means that the element or article occurring before this word encompasses the element or article and the equivalent thereof enumerated after this word and does not exclude other elements or articles. The word, such as “above”, “below”, or the like, is only used to indicate a relative position relationship. After the absolute position of a described object is changed, the relative position relationship may be changed accordingly.

In this disclosure, a “first/second active area” refers to an area where a first active layer or a second active layer is formed. A “non-active area” refers to an area where neither a first active layer nor a second active layer is formed and the base needs to be exposed by etching. However, another active layer, except a first active layer or a second active layer, may be otherwise formed in the non-active area according to practical needs, and this is encompassed in the scope of this invention.

Meanings of reference numerals in the drawings are as follows: 1, 11—LTPS TFT; 2, 22—oxide TFT; 10, 110—substrate; 20—buffering layer; 30, 130—polycrystalline silicon layer (low temperature polycrystalline silicon layer); 40, 140—oxide semiconductor layer; 50—passivation layer; 201, 1201—gate electrode insulating layer; 102, 202, 1102, 1202—gate electrode; 203, 1203—interlayer insulating layer; 104, 204, 1104, 1204—source electrode; 105, 205, 1105, 1205—drain electrode.

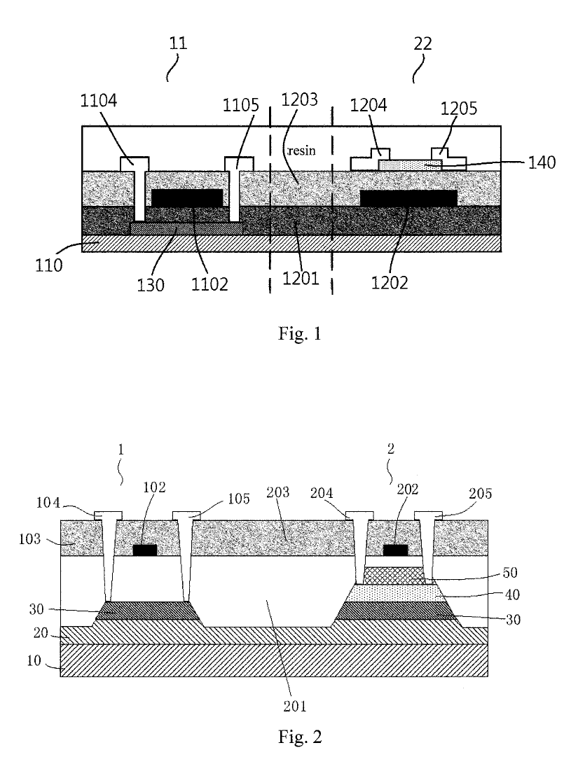

FIG. 1 is a structural schematic diagram of an LTPO TFT array substrate in the prior art. As shown in FIG. 1, the so-called LTPO process is forming an LTPS TFT 11 as a peripheral circuit area by a LTPS process and forming an oxide TFT 22 as a pixel area by an oxide process.

As shown in FIG. 1, the LTPS TFT 11 has a glass substrate 110, a polycrystalline silicon layer 130 formed on the glass substrate 110, a gate electrode insulating layer 1201 covering the polycrystalline silicon layer 130, a gate electrode 1102 formed on the gate electrode insulating layer 1201, an interlayer insulating layer 1203 covering the gate electrode 1102, and a source electrode 1104 and a drain electrode 1105 which are each connected to the polycrystalline silicon layer 130 through a via hole penetrating the interlayer insulating layer 1203 and the gate electrode insulating layer 1201. The TFT formed by using the LTPS process has the advantage of high electron mobility and thus the integration degree of the peripheral circuit can be improved, and the data-driven integrated circuit (IC) is reduced by using a multiplexer (MUX) and thus the cost can be reduced. As shown in FIG. 1, the oxide TFT 22 has a glass substrate 110, a gate electrode insulating layer 1201 formed on the glass substrate 110, a gate electrode 1202 formed on the gate electrode insulating layer 1201, an interlayer insulating layer 1203 covering the gate electrode 1202, an oxide semiconductor layer 140 formed on the interlayer insulating layer 1203, and a source electrode 1204 and a drain electrode 1205 connected to the oxide semiconductor layer 140. Since the TFT formed by the oxide process has a very low drain current, low-frequency driving may be achieved. The TFT formed by the LTPO process can combine the very advantages of both of them. However, an existing LTPO process is required to perform an existing LTPS process and an existing oxide process, and therefore at least two masks are required to form an active layer of an LTPS TFT and an active layer of an oxide TFT respectively, even if the masks in the photolithographic procedure are minimized Therefore, the number of masks used is relatively large, and the procedures become complex.

This invention is achieved in order to at least partly solve the technical problem described above, and is described in detail below in conjunction with specific embodiments.

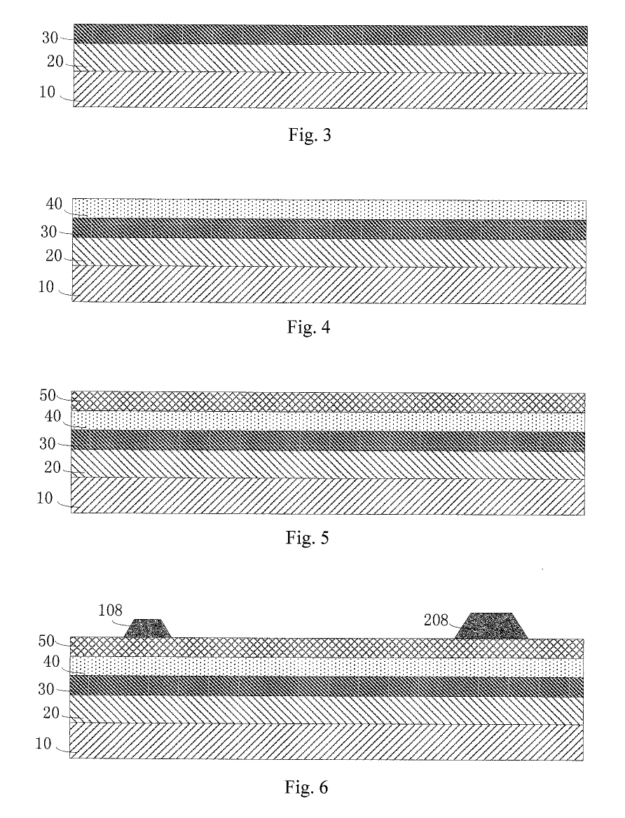

FIG. 2 is a structural schematic diagram of an LTPO TFT array substrate provided by an embodiment of this invention. As shown in FIG. 2, The LTPO TFT array substrate in an embodiment of this invention comprises an LTPS TFT 1 and an oxide TFT 2 adjacent to this LTPS TFT 1. In this embodiment, either of the LTPS TFT 1 and the oxide TFT 2 uses a top-gate type structure, but this invention is not limited thereto.

As shown in FIG. 2, the LTPS TFT 1 has a substrate 10, a buffering layer 20 formed on the substrate 10 (the substrate 10 and the buffering layer 20 correspond to a base), a polycrystalline silicon layer 30 (first active layer) formed on the buffering layer 20, a gate electrode insulating layer 201 covering the polycrystalline silicon layer 30, s gate electrode 102 (first gate electrode) formed on the gate electrode insulating layer 201, an interlayer insulating layer 203 covering the gate electrode 102, and a source electrode 104 (first source electrode) and a drain electrode 105 (first drain electrode) which are each connected to the polycrystalline silicon layer 30 through a via hole penetrating the interlayer insulating layer 203 and the gate electrode insulating layer 201.

Furthermore, as shown in FIG. 2, the oxide TFT 2 has a substrate 10, a buffering layer 20 formed on the substrate 10, a polycrystalline silicon layer 30 formed on the buffering layer 20, an oxide semiconductor layer 40 formed on the polycrystalline silicon layer 30 (the polycrystalline silicon layer 30 and the oxide semiconductor layer 40 correspond to a second active layer), a passivation layer 50 formed on the oxide semiconductor layer 40, a gate electrode insulating layer 201 covering the passivation layer 50, a gate electrode 202 (second gate electrode) formed on the gate electrode insulating layer 201, an interlayer insulating layer 203 covering the gate electrode 202, and a source electrode 204 (second source electrode) and a drain electrode 205 (second drain electrode) which are each connected to the oxide semiconductor layer 40 through a via hole penetrating the interlayer insulating layer 203 and the gate electrode insulating layer 201.

Here, the substrate 10 is, for example, a glass substrate. Furthermore, the gate electrode insulating layer 201 may be composed of, for example, silicon dioxide or silicon nitride. The interlayer insulating layer 203 may also be composed of, for example, silicon dioxide or silicon nitride. The buffering layer 20 may be formed by using the prior art, and detailed description is not made herein.

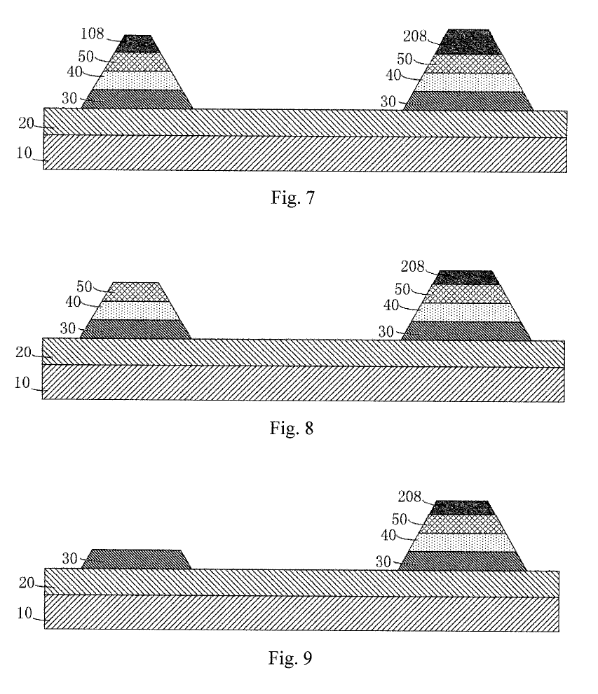

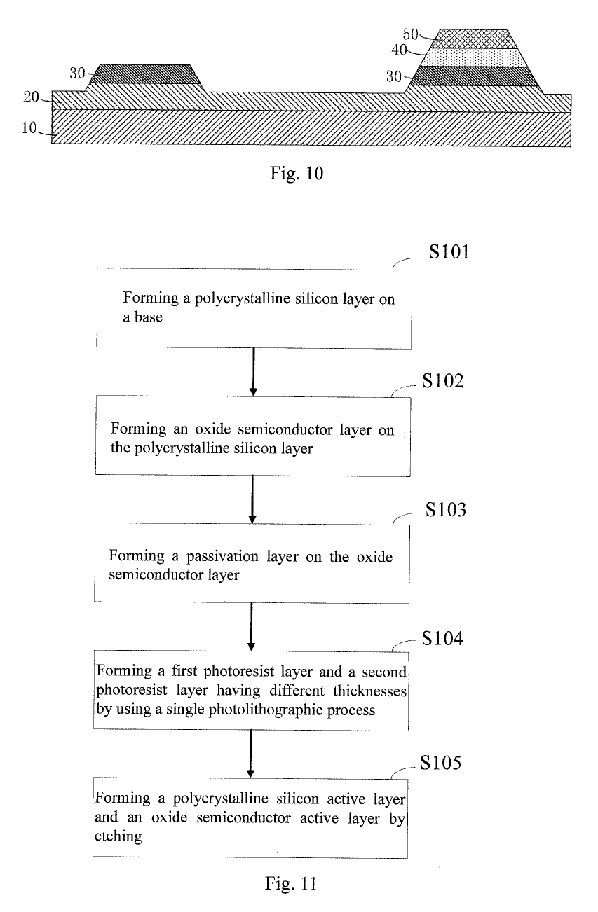

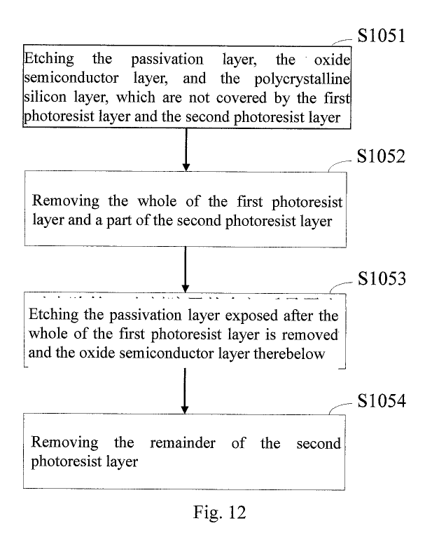

FIGS. 3-10 are schematic diagrams of various stages showing the production procedures of the active layer of the LTPO TFT array substrate in FIG. 2 according to an embodiment of this invention. FIG. 11 is a flow chart showing the production procedures of the active layer of the LTPO TFT array substrate in FIG. 2 according to an embodiment of this invention. FIG. 12 is a flow chart showing specific contents of step S205 in FIG. 11 according to an embodiment of this invention. The production method of the active layer of the LTPO TFT array substrate is specifically described below in conjunction with FIGS. 3-10.

As shown in FIG. 3, preferably in step S101 shown in FIG. 11, a buffering layer 20 is deposited on a substrate 10, an amorphous silicon (a-Si) layer is deposited on the buffering layer 20, and then a polycrystalline silicon (P-Si) layer 30 is formed by a procedure of excimer laser annealing (ELA).

As shown in FIG. 4, in step S102 shown in FIG. 11, an oxide semiconductor layer 40 is deposited on the polycrystalline silicon layer 30. This oxide semiconductor layer 40 may comprise at least one of IGZO (indium gallium zinc oxide), IGO (indium gallium oxide), ITZO (indium tin zinc oxide), and AlZnO (aluminum zinc oxide).

As shown in FIG. 5, in step S203 shown in FIG. 11, a passivation layer 50 is deposited on the oxide semiconductor layer 40. This passivation layer 50 may be composed of SiO₂. This passivation layer 50 has a relatively great effect on properties of the oxide semiconductor layer 40, and therefore the conditions of the procedure are very important. Typically, the passivation layer formed on the oxide semiconductor layer is formed from a plurality of layers. The passivation layer immediately on the oxide semiconductor layer is formed by a low-temperature procedure (for example, 170-250° C.) in most cases. In one embodiment of this invention, in order to ensure properties of the oxide semiconductor layer 40, a passivation layer is preferably formed. At a low temperature, for example at 170-250° C., a SiO₂ layer having a thickness of about 0.1 μm is deposited. This is for ensuring properties of the oxide semiconductor layer 40 and protecting the oxide semiconductor layer 40 in subsequent procedures.

As shown in FIG. 6, in step S104 shown in FIG. 11, a first photoresist layer 108 is formed at the first active area of the region of the LTPS TFT 1 (based on half tone) and a second photoresist layer 208 is formed at the second active area of the region of the oxide TFT 2 (based on full tone) by using a single mask in a single photolithographic procedure. As shown in FIG. 6, the first photoresist layer (first protective layer) 108 and the second photoresist layer (second protective layer) 208 cover the passivation layer 50 at the first active area and the second active area respectively, and have different thicknesses. For example, the thickness of the first photoresist layer 108 may be 0.5 μm, and the thickness of the second photoresist layer 208 may be 2 μm. Here, the photolithographic procedure described above is achieved by providing different transmittabilities at different positions of the mask.

Since the first photoresist layer 108 and the second photoresist layer 208 can be concurrently formed by using one mask in the same photolithographic procedure, the photolithographic procedure can be simplified and the production can be improved for an existing plant so as to increase the profit, and the investment cost can be effectively reduced for a newly established plant.

As shown in FIG. 10, in step S105 shown in FIG. 11, by etching, the followings are formed: the active layer of the LTPS TFT 1, i.e., the polycrystalline silicon layer 30 (first active layer); and the active layer of the oxide TFT 2, i.e., the polycrystalline silicon layer 30 and the oxide semiconductor layer 40 (second active layer). Here, the passivation layer 50 above the oxide semiconductor layer 40 in the oxide TFT 2 is remained so as to protect the oxide semiconductor layer 40 and ensure properties of the oxide semiconductor layer 40 in subsequent procedures.

Furthermore, the etching in step S105 may be performed according to the process flow in FIG. 12.

First, as shown in FIG. 7, in step S1051 shown in FIG. 12, the passivation layer 50, the oxide semiconductor layer 40, and the polycrystalline silicon layer 30 of the non-active area, which are not covered by the first photoresist layer 108 and the second photoresist layer 208, are etched. If wet etching is selected for the etching of the oxide semiconductor layer 40, then the passivation layer 50, the oxide semiconductor layer 40, and the polycrystalline silicon layer 30 of the non-active area, which are not covered by the first photoresist layer 108 and the second photoresist layer 208, may be sequentially etched in an order of dry etching, wet etching, and dry etching. The disadvantage of etching in this way is relatively complex procedures. Preferably, dry etching may be selected for the etching of the oxide semiconductor layer 40. In one procedure, the passivation layer 50, the oxide semiconductor layer 40, and the polycrystalline silicon layer 30 of the non-active area, which are not covered by the first photoresist layer 108 and the second photoresist layer 208, are sequentially etched by changing the etching gas. The structure after the etching is complete is as shown in FIG. 7.

Then, as shown in FIG. 8, in step S1052 shown in FIG. 12, the whole of the first photoresist layer 108 and a part of the second photoresist layer 208 are removed by ashing. At this time, the thickness of the remainder of the second photoresist layer 208 may be, for example, 1 μm.

Then, as shown in FIG. 9, in step S1053 shown in FIG. 12, the passivation layer 50 exposed after the whole of the first photoresist layer 108 is removed and the oxide semiconductor layer 40 therebelow are etched to form the active layer of the LTPS TFT 1, i.e., the polycrystalline silicon layer 30. In this step, those similar to step S1051 may also be performed. If wet etching is selected for the etching of the oxide semiconductor layer 40, then the exposed passivation layer 50 and the oxide semiconductor layer 40 therebelow may be sequentially removed in an order of dry etching and wet etching. However, the exposed passivation layer 50 and the oxide semiconductor layer 40 therebelow may be sequentially removed using dry etching by changing the etching gas in one procedure, and thus the procedures may be simplified.

Finally, as shown in FIG. 10, in step S1054 shown in FIG. 12, the remainder of the second photoresist layer 208 is removed by stripping, and thereby the active layer of the oxide TFT 2 is formed and the passivation layer 50 above the active layer of the oxide TFT 2 is remained. That is, the active layer of the oxide TFT 2 of is composed of the polycrystalline silicon layer 30 and the oxide semiconductor layer 40.

The procedure of forming the active layer of the LTPO TFT is complete by the above steps. As described above, in this embodiment, the active layer of the LTPS TFT 1 and the active layer of the oxide TFT 2 are formed by using a single patterning process (using one mask and performing a single photolithographic procedure).

After the active layer is formed, the procedures of forming gate electrode insulating layers, gate electrodes, interlayer insulating layers, source electrodes, and drain electrodes of the LTPS TFT 1 and the oxide TFT 2 are the same as those in the prior art, and therefore detailed description is not made herein. Concerning a contact region in the oxide TFT 2, since this contact region will become conductive when the interlayer insulating layer 203 is etched, there is no problem with contact.

After the source electrode and the drain electrode of the LTPS TFT 1 and the source electrode and the drain electrode of the oxide TFT 2 are formed, desirable layers may be formed according to the requirements of liquid crystal displays (LCDs) or organic light emitting diodes (OLEDs), and detailed description is not made herein.

With respect to the production method of the LTPO TFT array substrate according to an embodiment of this invention, since the active layer of the LTPS TFT and the active layer of the oxide TFT may be formed by using only one mask in the same photolithographic procedure, the procedures can be simplified and the production can be improved so as to increase the profitability.

Furthermore, in the LTPO TFT array substrate in an embodiment of this invention, the active layer of the oxide TFT 2 is composed of the oxide semiconductor layer 40 and the polycrystalline silicon layer 30 therebelow. Since the oxide semiconductor layer is highly sensitive to ultraviolet, it is advantageous to block ultraviolet by the polycrystalline silicon layer 30 below the oxide semiconductor layer 40.

The following points should be demonstrated: (1) the accompanying drawings of the embodiments of this invention merely relate to the structures related to the embodiments of this invention, and with respect to other structures, general designs may be referred to; and (2) thicknesses and shapes of various layers in the accompanying drawings do not reflect real ratios, and the object thereof is merely to exemplarily illustrate the embodiments of this invention.

Those described above are merely exemplary embodiments of this invention, but are not intended to limit the scope of this invention. The scope protected by this invention is determined by the appended claims.

What is claimed is:

1. A production method of an array substrate, comprising the steps of:
forming a polycrystalline silicon layer on a base, wherein the base comprises a first active area, a second active area, and a non-active area;
forming an oxide semiconductor layer on the polycrystalline silicon layer; and
forming a first active layer on the first active area and forming a second active layer on the second active area by using a single patterning process, wherein the first active layer is composed of the polycrystalline silicon layer, and the second active layer is composed of the oxide semiconductor layer and the polycrystalline silicon layer.

2. The production method of an array substrate according to claim 1, wherein
the patterning process comprises:
Step one: forming a first protective layer at the first active area and forming a second protective layer at the second active area by using a single mask, wherein the thickness of the first protective layer is less than that of the second protective layer;
Step two: removing the oxide semiconductor layer and the polycrystalline silicon layer at the non-active area by etching;
Step three: removing the whole of the first protective layer and a part of the second protective layer to expose the oxide semiconductor layer below the first protective layer;
Step four: removing the exposed oxide semiconductor layer by etching to form the first active layer composed of the polycrystalline silicon layer; and
Step five: removing the remainder of the second protective layer to form the second active layer composed of the oxide semiconductor layer and the polycrystalline silicon layer.

3. The production method of an array substrate according to claim 1, further comprising:
a step of forming a passivation layer on the oxide semiconductor layer before performing the patterning process, wherein
the patterning process comprises:
Step one: forming a first protective layer at the first active area and forming a second protective layer at the second active area by using a single mask, wherein the thickness of the first protective layer is less than that of the second protective layer;
Step two: removing the passivation layer, the oxide semiconductor layer, and the polycrystalline silicon layer at the non-active area by etching;
Step three: removing the whole of the first protective layer and a part of the second protective layer to expose the passivation layer below the first protective layer;
Step four: removing the exposed passivation layer and the oxide semiconductor layer therebelow by etching to form the first active layer composed of the polycrystalline silicon layer; and
Step five: removing the remainder of the second protective layer to form the second active layer composed of the oxide semiconductor layer and the polycrystalline silicon layer, and remaining the passivation layer on the second active layer.

4. The production method of an array substrate according to claim 2, wherein
the etching in the Step two and the Step four is dry etching.

5. The production method of an array substrate according to claim 3, wherein
the etching in the Step two and the Step four is dry etching.

6. The production method of an array substrate according to claim 2, wherein
in the Step two, the oxide semiconductor layer and the polycrystalline silicon layer at the non-active area are sequentially removed in an order of wet etching and dry etching,
and in the Step four, the exposed oxide semiconductor layer is removed by wet etching.

7. The production method of an array substrate according to claim 3, wherein
in the Step two, the passivation layer, the oxide semiconductor layer, and the polycrystalline silicon layer at the non-active area are sequentially removed in an order of dry etching, wet etching, and dry etching.

8. The production method of an array substrate according to claim 3, wherein
in the Step four, the exposed passivation layer and the oxide semiconductor layer therebelow are sequentially removed in an order of wet etching and dry etching.

9. The production method of an array substrate according to claim 1, wherein
the oxide semiconductor layer has a material comprising at least one of indium gallium zinc oxide, indium gallium oxide, indium tin zinc oxide, and aluminum zinc oxide.

10. The production method of an array substrate according to claim 3, further comprising the steps of:
forming a gate insulating layer;
forming a first gate electrode in the first active area and a second gate electrode in the second active area;
forming an interlayer insulating layer; and
forming a first source electrode and a first drain electrode in the first active area, and a second source electrode and a second drain electrode in the second active area,
wherein the first source electrode and the first drain electrode are each connected to the first active layer through a via hole which penetrates the interlayer insulating layer and the gate insulating layer, and
the second source electrode and the second drain electrode are each connected to the second active layer through a via hole which penetrates the interlayer insulating layer, the gate insulating layer, and the passivation layer.

11. An array substrate produced by the production method of claim 1, comprising:
a base, a gate electrode insulating layer, at least one gate electrode, at least one source electrode, and at least one drain electrode,
wherein the base has a first active area, a second active area, and a non-active area;
a first active layer is provided on the first active area and the first active layer is composed of a polycrystalline silicon layer,
a second active layer is provided on the second active area and the second active layer is composed of a polycrystalline silicon layer and an oxide semiconductor layer formed on the polycrystalline silicon layer,
and the polycrystalline silicon layer in the first active layer and the polycrystalline silicon layer in the second active layer are formed from the same polycrystalline silicon layer.

12. The array substrate according to claim 11, wherein
a passivation layer is further provided above the second active layer.

13. The array substrate according to claim 11, wherein
the oxide semiconductor layer has a material comprising at least one of indium gallium zinc oxide, indium gallium oxide, indium tin zinc oxide, and aluminum zinc oxide.

14. The array substrate according to claim 12, wherein
the oxide semiconductor layer has a material comprising at least one of indium gallium zinc oxide, indium gallium oxide, indium tin zinc oxide, and aluminum zinc oxide.

15. The array substrate according to claim 12, wherein
the array substrate further comprises an interlayer insulating layer,
the at least one gate electrode comprises a first gate electrode and a second gate electrode, the at least one source electrode comprises a first source electrode and a second source electrode, the at least one drain electrode comprises a first drain electrode and a second drain electrode,
the gate insulating layer is provided above the first active layer and the passivation layer,
the first gate electrode and the second gate electrode are provided above the gate insulating layer,
the interlayer insulating layer is provided above the first gate electrode and the second gate electrode,
the first source electrode, the first drain electrode, the second source electrode, and the second drain electrode are formed above the interlayer insulating layer,
wherein the first source electrode and the first drain electrode are each connected to the first active layer through a via hole which penetrates the interlayer insulating layer and the gate insulating layer, and
the second source electrode and the second drain electrode are each connected to the second active layer through a via hole which penetrates the interlayer insulating layer, the gate insulating layer, and the passivation layer.
